(19) United States
(12) Patent Application Publication
(10) Pub. No.: US 2008/0074299 A1
(43) Pub. Date: Mar. 27, 2008

(54) ELECTRICAL SIGNAL CONVERTING SYSTEM

(75) Inventors: Yao-jen Chang, Bancia City (TW); Ker-fu Bieh, Shindian City (TW)

Correspondence Address: MADSON & AUSTIN, 15 WEST SOUTH TEMPLE, SUITE 900, SALT LAKE CITY, UT, 84101, US

(73) Assignee: Benica Corporation, Shindian City (TW)

(21) Appl. No.: 11/837,413

(22) Filed: Aug. 10, 2007

(30) Foreign Application Priority Data
Sep. 22, 2006 (TW) 095217059

(51) Int. Cl. H03M 1/06

(52) U.S. Cl. 341/118

(57) ABSTRACT

An electrical signal converting system includes a housings a transmission interface slot group disposed on the housing, an OTG controller, and a system circuit. The transmission interface slot group is used for accommodating a first electrical memory card storing data consistent with a first storage standard. The OTG controller is used for accommodating a second electrical memory card storing data consistent with a second storage standard. The system circuit is used for converting the data consistent with the first storage standard into the data consistent with the second storage standard.

### BACKGROUND OF THE INVENTION

1. Field of the Invention

The present invention relates to an electrical signal converting system, more particularly, to an electrical signal converting system capable of converting various storage standards.

2. Description of the Related Art

In recent years, traditional memory cards for use in digital cameras, such as flash memory cards, are mostly-used SD standard. However, since mobile phones, Personal Digital Assistant (PDA), Global Positioning System (GPS), etc., have become popular, the demands of small-size memory cards have expanded rapidly. With the increasing number of digital cameras, mobile phones, portable video camcorder, MP3 players, and digital recording devices, the use of small-size memory cards increases. At present, various popular electrical memory cards are divided between a Secure Digital/Multi-Media Memory card (SD/MMC) memory card, a Compact Flash/Micro Drive (CF/MD) memory card, a Memory Stick (MS) memory card, a Smart Media (SM) memory card, and an eXtreme Digital (XD) memory card. Unfortunately, such memory cards are not compatible with one another.

So far, USB standard is a widely-used technology for data inter-transmission among various electrical devices. PCs can make a connection among various peripheral devices with different operating speeds in a simple way via USB interface that peripheral devices can transmit data under the control of PCs. However, without the PCs, the peripheral devices cannot operate via USB interface in such a convenient way. This is because a peripheral device with USB interface is always as a slave device if the PC as a host device does not exist.

Although USB interface has become one of the standard specifications in linking the PC and the peripheral devices, USB Implementer's Forum (USB-IF) composed of Intel, Microsoft, Philips, etc., creates a new specification which provides additional functions such as peer-to-peer and low power-consumption in the original USB specification, named as USB On-The-Go (OTG). With the OTG technology, one of peripheral devices can be set as a host device under a circumstance of no PC as a host device, so that data transmission between peripheral devices originally used as slave devices can still be realized. In this way, all USB products have the independent operation abilities, and are not only restricted to being peripheral devices of a computer For example, by means of USB interface of a digital camera, the digital camera is directly linked to a printer, which is able to print the pictures immediately via the OTG technology. Also, the data in the digital camera can be transmitted to the removable hard disk of the USB interface via the OTG technology. By utilizing the OTG technology, an electrical peripheral device not only serves as a slave device to communicate with a PC via the USB interface, but also the electrical peripheral device can serve as a host device to directly link with other slave devices. Therefore, the OTG technology brings more convenience to the users, and a memory card named as SQ memory card integrating both OTG device standard and USB standard has been developed

As a result, a development of an electrical system capable of inter-data-transmission among memory cards, such as Secure Digital/Multi Media Memory card (SD/MMC) memory card, a Compact Flash/Micro Drive (CF/MD) memory card, a Memory Stick (MS) memory card, a Smart Media (SM) memory card, an eXtreme Digital (XD) memory card, and an SQ card using OTG device standard, is a trend in the industry

### SUMMARY OF INVENTION

According to the claimed invention, an electrical signal converting system comprises a housing, a transmission interface slot group disposed on the housing, an OTG controller, and a system circuit. The transmission interface slot group is used for accommodating a first electrical memory card storing data consistent with a first storage standard The OTG controller is used for accommodating a second electrical memory card storing data consistent with a second storage standard. The system circuit is used for converting the data consistent with the first storage standard into the data consistent with the second storage standard.

According to the claimed invention, an electrical signal converting system comprises an housing, a first transmission interface disposed on the housing, a second transmission interface disposed on the housing, a controller, and a system circuit. The first transmission interface comprises a plurality of data pins and an identification pin, and is used for accommodating a first electrical memory card storing data consistent with a first storage standard. The second transmission interface is used for accommodating a second electrical memory card storing data consistent with a second storage standard. The controller is used for identifying whether the identification pin is electrically connected to the first electrical memory card. The system circuit is used for converting the data consistent with the first storage standard into the data consistent with the second storage standard, or converting the data consistent with the second storage standard into the data consistent with the first storage standard, when the identification pin is electrically connected to the first electrical memory card.

The disclosed inventions will be described with reference to the accompanying drawings, which show important sample embodiments of the invention and which are incorporated in the specification hereof by reference.

### BRIEF DESCRIPTION OF THE DRAWINGS

FIG. 1 shows an electrical signal converting system according to a preferred embodiment of the present invention.

FIG. 2 is a block diagram of the electrical signal converting system depicted in FIG. 1.

FIG. 3 shows an electrical signal converting system according to another preferred embodiment of the present invention.

FIG. 4 shows an electrical signal converting system according to a third preferred embodiment of the present invention.

### DETAILED DESCRIPTION OF THE PREFERRED EMBODIMENT

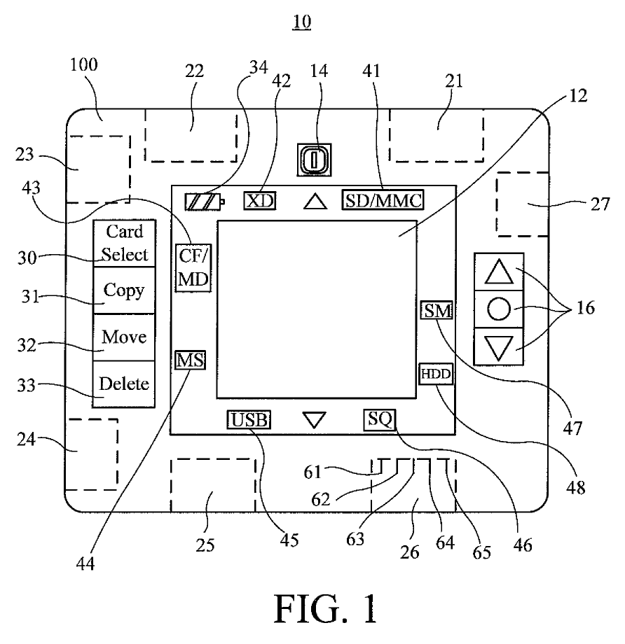

Please refer to FIG. 1 which shows an electrical signal converting system 10 according to a preferred embodiment of the present invention. The Electrical signal converting system 10 comprises a housing 100, a display screen 12 disposed on the housing 10, operating buttons 14, 16, 30, 31, 32 and 33 disposed on sides of the display screen 12, indicating lights 34, 41, 42, 43, 44, 45, 46, 47 and 48 disposed around the display screen 12, and a plurality of transmission interface (areas represented by dotted lines in FIG. 1), implemented as slots and disposed on the four sides of the housing 100. Most indicating lights correspond to the plurality of transmission interfaces. The plurality of transmission interfaces are used for accommodating electrical memory cards with various storage standards and sizes. First transmission interfaces group is defined as data source end, while second transmission interface group is defined as data target end. As can been seen in FIG. 1, the first transmission interface group comprises a Secure Digital/MMC (SD/Multi Media Memory card) slot 21, an eXtreme Digital (XD) slot 22, a Compact Flash/Micro Drive (CF/MD) slot 23, a Memory Stick (MS) slot 24, and a Smart Media (SM) slot 27. Besides the slots 21, 22, 23, 24, 27, the second transmission interface group also comprises a Universal Serial Bus (USB) slot 25 and an SQ slot 26. The SD slot 21 is used for accommodating an SD/MMC electrical memory card. The XD slot 22 is used for accommodating an XD electrical memory card. The CF/MD slot 23 is used for accommodating a CF/MD electrical memory card. The MS slot 24 is used for accommodating an MS electrical memory card. The USB slot 25 is used for accommodating the electrical memory card or an electrical device using USB standard. The SQ slot 26 is used for accommodating the electrical memory card or the electrical storage device using USB On-The-Go (abbreviated as OTG hereinafter) device standard. An SM slot 27 is used for accommodating an SM electrical memory card. It should be understood to the ordinary skilled person in the art that the transmission interfaces are not limited to the slots aforementioned, other transmission interfaces using different transmission standards are also allowed.

First, the user can press the power button 14 to enable the electrical signal converting system 10, and a power indicating light 34 shows the rest amount of power. Then, the user put an electrical memory card or a storage medium into a corresponding slot. If the electrical memory card is accurately inserted into the slot and is activated, the corresponding indicating light lights up, otherwise, the corresponding indicating light does not light up. When the electrical memory card is activated, the indicating light flickers. The user can manipulate the electrical signal converting system 10 to transmit data stored in the electrical memory card which is being inserted into the first transmission interface group (serving as a data source end) to another electrical memory card which is being inserted into the second transmission interface group (serving as a data target end). For instance, if the user intends to transfer digital data stored in a USB electrical memory card to a SD/MMC electrical memory card, the user can insert the SD/MMC electrical memory card into the SD/MMC slot 21, and insert the USB electrical memory card or electrical storage devices using USB standard (such as a USB portable storage drive, an MP3 player) into the USB slot 25, and execute commands by means of pressing buttons on the housing 100 to perform data transmission. In a duration of data transmission between the USB electrical memory card inserted within the USB slot 25 and the SD/MMC electrical memory card inserted within SD/MMC slot 21, the indicating lights 41, 45 flicker. Similarly, in a duration of data transmission between the SQ electrical memory card using OTG standard inserted within the SQ slot 26 and the SD/MMC electrical memory card inserted within SD/MMC slot 21, the indicating lights 41, 46 flicker.

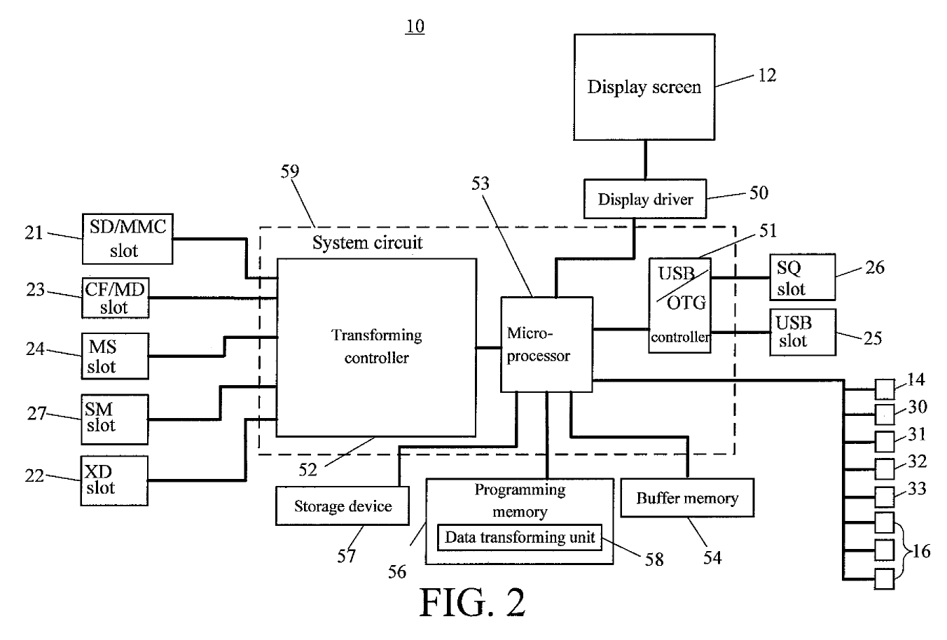

Please refer to FIGS. 1 and 2. FIG. 2 is a block diagram of the electrical signal converting system 10 depicted in FIG. 1. The electrical signal converting system 10 comprises a display driver 50, a system circuit 59, a buffer memory 54, a programming memory 56 and a storage device 57 enclosed within the housing 100. The system circuit 59 further comprises a transforming controller 52, a USB/OTG controller 51, and a microprocessor 53. Preferably, the microprocessor 53, the USB/OTG controller 51 and/or the transforming controller 52 can be integrated as a single chip. Once no power is supplied, the storage device 57, for example a hard disk, can store data which is originally stored in one of the SD/MMC, XD), CF/MD, MS, SM electrical memory cards, the electrical memory card or electrical device using USB standard, or the electrical memory card or electrical device using OTG standard.

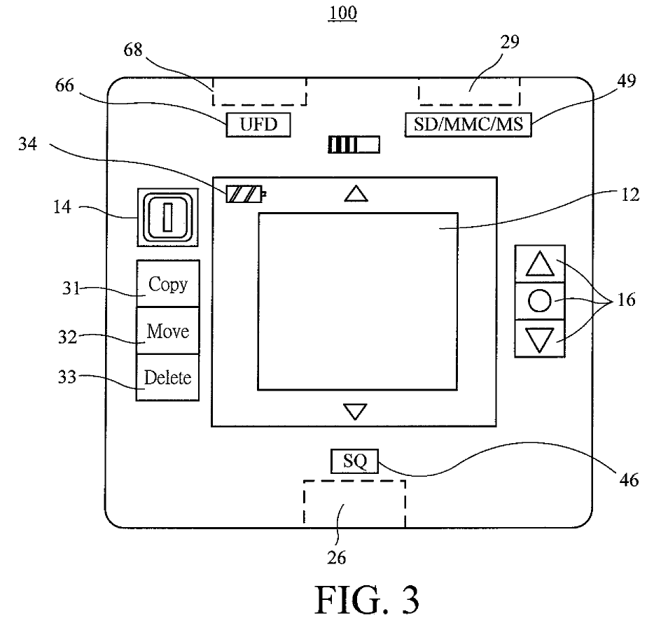

The SQ slot 26 comprises an identification end 62 and ends 61, 63, 64, 65, five ends consistent with USB On-The-Go (OTG) device standard. The ends 61, 63, 64, 65 corresponds to two data transmission pins D+, D− and voltage supply pins V_{BUS}, Gnd of the USB electrical memory card. The USB/OTG controller 51 can determine a host/slave relationship based on whether the identification end 62 is electrically connected to a corresponding pin of the USB electrical memory card. For example, if the identification end 62 is not electrically connected to the corresponding pin of the USB electrical memory card, the USB/OTG controller 51 serves the USB electrical memory card as a slave device and serves the electrical signal converting system 10 as a host device. In addition, the electrical signal converting system 10 further comprises a data transforming unit 58 which is implemented by computer code stored in the programming memory 56 or implemented by a hardware circuit. The data transferring unit 58 is used for storage standard-transferring among various storage standards. The programming memory 56 also stores operation computer code for controlling the electrical signal converting system 10. The operation computer code is used for performing copy file, delete file, move file, Graphic user interface (GUI) or operating system (OS). The microprocessor 53 can read required operation computer code from the programming memory and perform the read operation computer code. The display driver 50 can control the display screen 12 to show the result performed by the microprocessor 53. The display screen 12 may be a liquid crystal display (LCD) panel or a light emitting diode (LED) panel. The transforming controller 52 comprises various controllers for accessing various electrical memory cards, for example, a controller for accessing an SD/MMC electrical memory card, a controller for accessing an XD electrical memory card, a controller for accessing a CF/MD electrical memory card, a controller for accessing an MS electrical memory card, and accessing an SM electrical memory card. The transforming controller 52 identifies each storage standard of data of the electrical memory cards inserted into the slots 21, 22, 23, 24, 27. As shown in FIG. 3 showing another embodiment of the electrical signal converting system 100 according to the present invention, part function of the electrical signal converting system 100 shown in FIG. 3 is omitted. The display screen 12 is a light emitting diode panel, and the SD/MMC slot and the MS slot are integrated as an SD/MMC/MS slot 29 which is used for accommodating the SD/MMC or the MS electrical memory card. The electrical signal converting system 100 can access the data stored in the SD/MMC or the MS electrical memory cards by means of the SD/MMC/MS slot 29. When the SD/MMC or the MS electrical memory card accommodated within the SD/MMC/MS slot 29 is accessed, an SD/MMC/MS indicating light 49 lights up. Moreover, a UFD slot 68 is used for accommodating an electrical memory device using USB interface standard, such as USB flash drive. Similarly, when the electrical device using USB interface standard is inserted into the UFD slot 68 and is accessed, a UFD indicating light 66 also lights up.

When two or more electrical memory cards are inserted into their corresponding slots, the user can control data processing between the electrical memory cards by means of a user interface shown on the display screen 12. For example, if the SQ electrical memory card, the MS electrical memory card, and the CF electrical memory card are respectively inserted into the SQ slot 26, MS slot 24 and the CF/MD slot 23, the user can transfer data stored in the SQ electrical memory card to the MS electrical memory card and the CF electrical memory card. After pressing a “Card Select” button 30 to select one of the SQ, MS and CF electrical memory cards, the user can select required data stored in the SQ electrical memory card by pressing the operating buttons 16. Thereafter, the user can press a “Delete” button 33 to delete the selected data, or press a “Copy” button 31 to duplicate the selected data or press a “Move” button 32 to move the selected data to another memory card. If the user wants to copy data stored in the SQ electrical memory card to the MS electrical memory card, the user can press the “Copy” button 31 to duplicate the selected data to the buffer memory 54, and press the “Card Select” button 30 to assign the MS electrical memory card, and then transferred the selected data to the MS electrical memory card within the MS slot 24. It is appreciated that a data conversion from the OTG standard to MS standard is performed by means of the transforming controller 52 when the “Card Select” button 30 is pressed. If the “Move” button 32 is pressed, the similar mechanism is introduced in the copy process except a removal of the original selected data stored in the SQ electrical memory card after the selected data is duplicated in the MS electrical memory card. If the user wants to copy the data in the CF electrical memory card to the SQ electrical memory card, the user can press the “Card Select” button 30 to assign the CF electrical memory card, and the data in the CF electrical memory card is read by the transforming controller 52 and transformed to the OTO standard (compatible with the SQ electrical memory card) by the microprocessor 53 based on the data transforming unit 58. Finally, the transformed data is temporarily stored in the buffer memory 54 and is transferred to SQ electrical memory card through the USB/OTG controller 51.

The electrical signal converting system 100 not only transfers data between the electrical memory cards and the electrical devices inserted the slots thereof but also stores data stored in the electrical memory cards and the electrical devices to the storage device 57. When the data is being transferred to the storage device 57, the HDD indicating light 48 lights up.

It is appreciated that the buffer memory can be a Random Access memory (RAM).

Even though, in the embodiments, only SQ, CF, MS electrical memory cards are introduced, a data transmission between any electrical memory cards and the electrical devices inserted into corresponding slots 21, 22, 23, 24, 25, 26, 27 of the electrical signal converting system 100 is allowed as similar mechanism aforementioned.

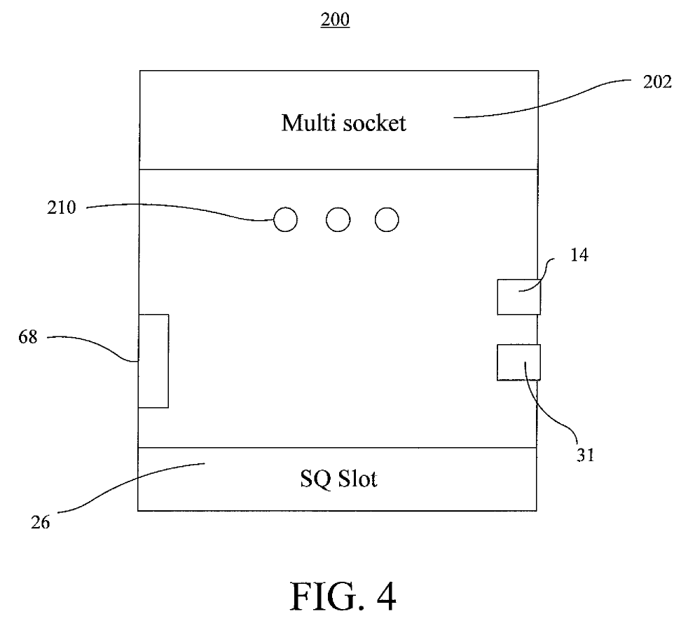

Please refer to FIG. 4, which shows an electrical signal converting system 200 according to a third preferred embodiment of the present invention. The electrical signal converting system has a multi-socket 202, a power button 14, a copy button 31, the UFD slot 68, a plurality of LEDs 210, and a SQ slot 26. When a SD (or a SD, a MMC, a MS, a CF, a XD) memory card is inserted into the multi-socket 202 and a SQ memory card is being inserted into the SQ slot 26, the data inter-transmission between the SQ memory card inserted into the SQ slot 26 and the memory card inserted into the multi-socket 202 can be realized by pressing the copy button 31. At this moment, the LEDs 210 lights up. Similarly, when a SD (or a SD, a MMC, a MS, a CF, a XD) memory card is inserted into the multi-socket 202 and a USB storage device is inserted into the UFD slot 68, the data inter-transmission between the SQ memory card inserted into the SQ slot 26 and the USB storage device inserted into the UFD slot 68 can be realized by pressing the copy button 31.

In addition, when a USB cable links the USB slot 25 of the electrical signal converting system 10 and a host electrical device, such as a personal computer, the data stored in the electrical memory cards inserted into the other slots can be accessed by the host electrical device. In other words, the electrical signal converting system 10 functions as a memory card reader which can access various electrical memory card by the host electrical device.

In contrast to prior art, the electrical signal converting system 10 according to the present invention can convert data stored in various electrical memory card using various storage standard, such that data transmission between the electrical memory cards is easily achieved without worrying about compatibility for different storage standards, tremendously facilitating the convenience in data storage and data transmission.

The present invention has been described with reference to certain preferred and alternative embodiments which are intended to be exemplary only and not limited to the full scope of the present invention as set forth in the appended claims.

What is claimed is:

1. An electrical signal converting system, comprising:
a housing;
a transmission interface slot group disposed on the housing, for accommodating a first electrical memory card storing data consistent with a first storage standard;
an OTG controller for accommodating a second electrical memory card storing data consistent with an second storage standard; and
a system circuit for converting the data consistent with the first storage standard into the data consistent with the second storage standard.

2. The electrical signal converting system of claim 1, wherein the system circuit comprises:
a transforming controller for identifying the data consistent with the first storage standard;
a programming memory, for storing a data transforming unit which is implemented by computer code, the data transforming unit providing a relationship between the first storage standard and the second storage standard; and
a microprocessor, for transforming the data consistent with the first storage standard into the second storage standard based on the data transforming unit.

3. The electrical signal converting system of claim 1, wherein the first storage standard is consistent with the storage standard of a Secure Digital (SD) electrical memory card or of a Multi-Media Memory card (MMC).

4. The electrical signal converting system of claim 1, wherein the first storage standard is consistent with the storage standard of a Compact Flash (CF) electrical memory card or of a Micro Drive (MD) electrical memory card.

5. The electrical signal converting system of claim 1, wherein the first storage standard is consistent with the storage standard of a Memory Stick (MS) electrical memory card.

6. The electrical signal converting system of claim 1, wherein the first storage standard is consistent with the storage standard of a Smart Media (SM) electrical memory card.

7. The electrical signal converting system of claim 1, wherein the first storage standard is consistent with the storage standard of an extreme Digital (XD) electrical memory card.

8. The electrical signal converting system of claim 1, wherein the second storage standard is consistent with an OTG standard or a USB standard.

9. The electrical signal converting system of claim 1, further comprising:
a first indicating light, for emitting light when the first electrical memory card is accommodated within the transmission interface slot group; and
a second indicting light, for emitting light when the second electrical memory card is accommodated within the OTG controller.

10. The electrical signal converting system of claim 1, further comprising a display screen disposed on the housing, for displaying the operation of the electrical signal converting system.

11. The electrical signal converting system of claim 10, wherein the display screen is a liquid crystal display panel or a light emitting diode panel.

12. The electrical signal converting system of claim 1, further comprising a storage device for storing the data consistent with the first storage standard or the second storage standard.

13. An electrical signal converting system, comprising:
a housing;
a first transmission interface disposed on the housing and comprising a plurality of data pins and an identification pin, for accommodating a first electrical memory card storing data consistent with a first storage standard;
a second transmission interface disposed on the housing, for accommodating a second electrical memory card storing data consistent with an second storage standard;
a controller, for identifying whether the identification pin is electrically connected to the first electrical memory card; and
a system circuit, for converting the data consistent with the first storage standard into the data consistent with the second storage standard, or converting the data consistent with the second storage standard into the data consistent with the first storage standard, when the identification pin is electrically connected to the first electrical memory card.

14. The electrical signal converting system of claim 13, wherein the system circuit comprises:
a transforming controller for identifying the data consistent with the first storage standard;
a programming memory, for storing a data transforming unit which is implemented by computer code, the data transforming unit providing a relationship between the first storage standard and the second storage standard; and
a microprocessor, for transforming the data consistent with the first storage standard into the second storage standard, or transforming the data consistent with the second storage standard into the first storage standard, based on the data transforming unit.

15. The electrical signal converting system of claim 13, wherein the first storage standard is consistent with the storage standard of a Secure Digital (SD) electrical memory card or of a Multi Media Memory card (MMC).

16. The electrical signal converting system of claim 13, wherein the first storage standard is consistent with the storage standard of a Compact Flash (CF) electrical memory card or of a Micro Drive (MD) electrical memory card.

17. The electrical signal converting system of claim 13, wherein the first storage standard is consistent with the storage standard of a Memory Stick (MS) electrical memory card.

18. The electrical signal converting system of claim 13, wherein the first storage standard is consistent with the storage standard of a Smart Media (SM) electrical memory card.

19. The electrical signal converting system of claim 13, wherein the first storage standard is consistent with the storage standard of an extreme Digital (XD) electrical memory card.

20. The electrical signal converting system of claim 13, wherein the second storage standard is consistent with an OTG standard or a USB standard.

21. The electrical signal converting system of claim 13, further comprising:
a first indicating light, for emitting light when the first electrical memory card is accommodated within the first transmission interface; and
a second indicting light, for emitting light when the second electrical memory card is accommodated within the second transmission interface.

22. The electrical signal converting system of claim 13, further comprising a display screen disposed on the housing, for displaying the operation of the electrical signal converting system.

23. The electrical signal converting system of claim 22, wherein the display screen is a liquid crystal display panel or a light emitting diode panel.

24. The electrical signal converting system of claim 13, wherein a host is linked to the first transmission interface via a cable, and the host is used for accessing the data consistent with the second storage standard stored in the second electrical memory card via the electrical signal converting system.
